(19) United States
(12) Patent Application Publication
(10) Pub. No.: US 2026/0291511 A1
(43) Pub. Date: Sep. 24, 2026

(54) METHODS AND SYSTEMS FOR ERROR CANCELATION OF MAC ADC SYSTEM

(71) Applicants: Vishal Sarin, SARATOGA, CA (US); BIPRANGSHU SAHA, bangalore (IN); Sankha SAHA, SANTA CLARA, CA (US); Vikram Kowshik, Cupertino, CA (US); Sang T. Nguyen, union city, CA (US)

(72) Inventors: Vishal Sarin, SARATOGA, CA (US); BIPRANGSHU SAHA, bangalore (IN); Sankha SAHA, SANTA CLARA, CA (US); Vikram Kowshik, Cupertino, CA (US); Sang T. Nguyen, union city, CA (US)

(21) Appl. No.: 19/424,104

(22) Filed: Dec. 17, 2025

Related U.S. Application Data
(63) Continuation-in-part of application No. 19/227,425, filed on Jun. 3, 2025, now abandoned.
(60) Provisional application No. 63/655,574, filed on Jun. 3, 2024.

(51) Int. Cl. H03M 1/06; H03M 1/10

(52) U.S. Cl. CPC H03M 1/0602; H03M 1/1009

(57) ABSTRACT

A system for analog-to-digital conversion with error cancellation comprises an ADC with a charge-accumulating capacitor, reference voltage input, comparator, synchronizer flip- 15 flop, and value-capturing latch. The system includes an ADC control system featuring a finite state machine (FSM) that generates control signals, receives clock input, and accepts a delay trim input specifying delay values. The FSM delays an enable counter signal by a specific number of clock cycles based on the trim input value. A counter receives this delayed enable signal and generates values captured by the latch. This delayed counter operation implements systematic error cancellation by aligning the counter start time with the ADC's systematic error timing shift, effectively compensating for process and temperature-dependent errors that would otherwise affect conversion accuracy.

### CLAIM OF PRIORITY

This application claims priority to United States Provisional Patent Application No. 63/655,574, titled METHODS AND SYSTEMS FOR GAIN CONTROL OF ANALOG MAC ADC SYSTEM and filed on Jun. 3, 2024. This provisional application is hereby incorporated by reference in its entirety.

### BACKGROUND OF THE INVENTION

### 1. Field

This application generally relates to electronic circuits and, more particularly, to a system, method, and article of manufacture of utilizing ADC for analogue multiply-accumulator (MAC) application.

### 2. Background

A vital component of the neural network is a Multiplier-and-Accumulator (MAC) unit. An analog low-power implementation needs different analog parts, including an ADC (Analog to Digital Converter) to produce digital output upon completion of internal MAC operation in analog mode. Being an analog system, it is more prone to errors at different phases.

ADC acts as an accumulator for the MAC and converts the outcome to digital. In analog MAC systems, the accumulated result may represent the sum of a plurality of multiply operations whose effective dynamic range exceeds the native resolution of the ADC, thereby requiring techniques to selectively capture the most significant portion of the accumulated signal. Different sources of error have been identified with the ADC system, can be characterized as Randon and Systematic errors. The random errors due to variation can be handled using a Dual slope ADC system. The systematic errors of the ADC are process and temperature-dependent. These errors are generally independent of input data.

Moreover, Artificial neural networks have become increasingly important in various applications, including image recognition, natural language processing, and autonomous systems. A vital component of these neural networks is the Multiplier-and-Accumulator (MAC) unit, which performs the core mathematical operations required for neural network computation. In power-constrained environments, analog implementations of MAC units offer significant advantages in terms of energy efficiency compared to their digital counterparts.

Analog MAC implementations require Analog-to-Digital Converters (ADCs) to produce digital outputs upon completion of internal MAC operations in analog mode. These ADCs effectively serve as accumulators for the MAC units, converting the final analog results into digital form for subsequent processing. However, being analog systems, these implementations are more prone to various types of errors that can impact the accuracy and reliability of neural network computations.

The errors in ADC systems can be broadly categorized into random and systematic errors. Random errors, typically resulting from noise and variations in the manufacturing process, can be addressed using established techniques such as dual-slope ADC systems. In contrast, systematic errors present a more challenging problem, as they are process and temperature-dependent, yet generally independent of input data. These systematic errors often manifest as timing shifts in the ADC operation, where detection of reference voltage crossings occurs with a consistent delay or advance relative to the ideal detection time.

Current approaches to handle systematic errors in ADCs typically involve complex calibration procedures or additional circuitry that increase power consumption and silicon area. As neural network accelerators become more prevalent in edge computing and mobile devices where power efficiency is critical, there is a growing need for more elegant solutions to address systematic errors in analog MAC implementations without significant overhead.

Conventional error correction techniques often focus on post-processing of ADC outputs or implementing redundant circuitry, both of which can negate the power and area advantages offered by analog MAC implementations. Furthermore, existing solutions may require frequent recalibration to account for temperature variations, which is impractical in many deployment scenarios.

Therefore, there exists a need for methods and systems that can effectively cancel systematic errors in ADC systems used for analog MAC applications, particularly in neural network accelerators, without substantially increasing power consumption, silicon area, or operational complexity. The invention implements specific methods and systems by which systematic errors are cancelled out at their best.

### SUMMARY OF THE INVENTION

In one aspect, a system for analog-to-digital conversion with error cancellation includes an ADC comprising a capacitor for charge accumulation at a first node, a reference voltage input connected to the capacitor, a comparator with inputs from the first node and reference voltage, a synchronizer flip-flop connected to the comparator output, and a latch that captures counter values based on the flip-flop output. The system also includes an ADC control system with a finite state machine (FSM) that generates control signals for ADC operation, a clock input connected to the FSM, and a delay trim input that specifies delay values for the FSM. The FSM delays an enable counter signal by an integer number of clock cycles as defined by the delay trim input. A counter receives this enable signal from the FSM and generates values for the latch to capture. The delayed enable counter signal implements systematic error cancellation by making the counter start counting after a delay that corresponds to the systematic error timing shift in the ADC. In some embodiments, systematic error cancellation and effective dynamic-range alignment are achieved by selectively adjusting at least one of (i) a reference ramp applied to the ADC or (ii) a charge accumulation capacitance associated with the ADC, thereby altering a measurement range of the ADC without increasing ADC resolution.

In another aspect, a method for analog-to-digital conversion with error cancellation comprises several interconnected steps. The process begins by accumulating a charge at a first node of a capacitor in an analog-to-digital converter (ADC). A comparator then compares the voltage at this first node with a reference voltage, with the comparator having a first input coupled to the first node and a second input coupled to a reference voltage input. A finite state machine (FSM) generates one or more control signals for ADC operation while receiving both a clock input and a delay trim input, the latter specifying a delay value. The FSM delays an enable counter signal by an integer number of clock cycles defined by the delay trim input. A counter, coupled to receive the enable counter signal from the FSM, generates a counter value. A synchronizer flip-flop coupled to the output of the comparator synchronizes the comparator's output, after which a latch coupled to the synchronizer flip-flop's output captures the counter value. The method implements systematic error cancellation via the delayed enable counter signal by causing the counter to start counting after a delay that corresponds to a systematic error timing shift in the ADC. In some embodiments, the charge accumulation is performed using a selectable effective capacitance value so as to shift a portion of an accumulated analog signal into a resolvable range of the ADC.

### BRIEF DESCRIPTION OF THE DRAWINGS

FIG. 1 illustrates the ADC system used to convert the analog MAC output into digital data, according to some embodiments.

FIG. 2 depicts the ADC control system, which implements a finite state machine (FSM) that generates various control signals for ADC operation, according to some embodiments.

FIG. 3 shows the timing diagram of the ADC operation, according to some embodiments.

FIG. 4 illustrates a for implementing the error cancellation system in MAC ADC, according to some embodiments.

The Figures described above are a representative set and are not an exhaustive with respect to embodying the invention.

### DESCRIPTION

Disclosed are a system, method, and article of manufacture of error cancelation of MAC ADC system. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment of the present invention. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of the embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided.

Analog-to-Digital Converter (ADC) can be an electronic circuit that transforms continuous analog signals into discrete digital values that can be processed by digital systems. ADCs operate by sampling the analog input at specific time intervals and converting each sample into a digital code with a resolution determined by the number of bits in the converter. In the context of neural network MAC operations, ADCs serve as the interface between analog computation and digital processing, enabling power-efficient implementations while ensuring compatibility with digital systems for subsequent data manipulation.

Current mirror can be a circuit designed to copy a current through one active device by controlling the current in another active device of a circuit, keeping the output current constant regardless of loading.

Finite State Machine (FSM) can be a computational model used to design systems that can be in one of a finite number of states at any given time, with transitions between states determined by inputs and current state conditions. FSMs are fundamental building blocks in digital circuit design that can be implemented using sequential logic elements such as flip-flops to store state information and combinational logic to determine state transitions. In the context of the ADC error cancellation system, an FSM is employed to generate precisely timed control signals and to implement configurable delays for the counter enable signal, allowing the system to compensate for systematic timing errors.

GND refers to the universal Ground connection in electrical engineering. It is the reference point and represents a Zero potential for the entire circuit under discussion.

Multiply-Accumulate (MAC) unit can be a specialized electronic circuit that performs multiplication of two numbers and adds the result to an accumulator, executing both operations in a single computational step. MAC units serve as fundamental building blocks in digital signal processors, microprocessors, and neural network accelerators where they efficiently implement operations like dot products, convolutions, and matrix multiplications. In analog implementations, MAC units perform these operations using continuous signals rather than discrete digital values, offering significant power efficiency advantages for applications like neural networks, though they require ADCs (Analog-to-Digital Converters) to transform their analog outputs into digital form for subsequent processing.

N-type metal-oxide-semiconductor logic uses n-type (−) MOSFETs (metal-oxide-semiconductor field-effect transistors) to implement logic gates and other digital circuits. nMOS transistors operate by creating an inversion layer in a p-type transistor body. This inversion layer, called the n-channel, can conduct electrons between n-type source and drain terminals. The n-channel is created by applying voltage to the third terminal, called the gate. nMOS transistors have four modes of operation: cut-off (or subthreshold), triode, saturation (sometimes called active), and velocity saturation.

Operational amplifier (herein ‘op amp’) can be a DC-coupled high-gain electronic voltage amplifier with a differential input an n-ended output (e.g. a single-ended output).

A parasitic element is a circuit element that is possessed by an electrical component but which it is not desirable for it to have for its intended purpose.

### Example Computer Architecture and Systems

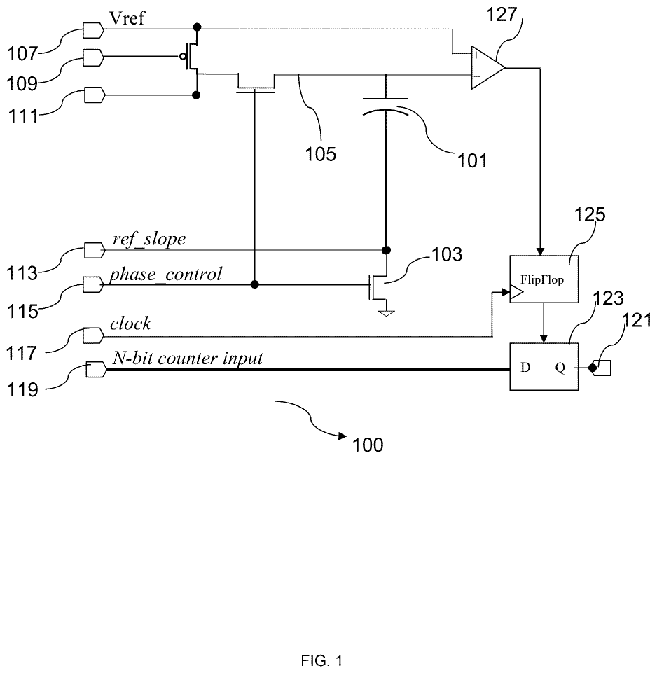

FIG. 1 illustrates the ADC system 100 used to convert the analog MAC output into digital data, according to some embodiments. Charge input to pin 111 accumulates in capacitor 101, which is initially charged to Vref via pin 107, over a specified period. A higher accumulated charge results in a lower potential across capacitor 101. During the evaluation phase, capacitor node 105 is recharged to Vref through the application of a reference slope signal on pin 113. The ADC implementation comprises comparator 127, a comparator output synchronizer flip-flop 125, and latch 123. Clock signal 117 and N-bit counter input 119 are supplied to the flip-flop 125 and latch 123, respectively.

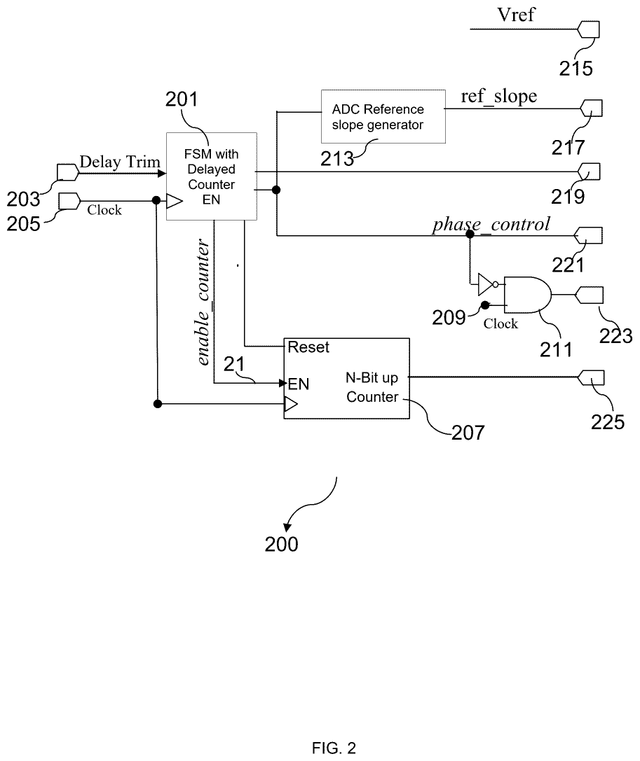

FIG. 2 depicts the ADC control system 200, which implements a finite state machine (FSM) 201 that generates various control signals for ADC operation, according to some embodiments. The FSM receives clock signal 205 for operational timing and a trim input 203 for delay configuration. FSM 201 delays the enable_counter signal 217 by an integer number of clock cycles as specified by trim input 203. Additionally, the FSM generates several other signals: 217 (ref_slope), 219 (precharge), and 221 (phase_control), wherein ref_slope controls a reference ramp rate applied to the accumulation capacitor and thereby modifies a time-based measurement range of the ADC. A high-to-low transition on signal 221 initiates the ADC evaluation phase. At the beginning of this evaluation phase triggered by the high-to-low transition of signal 221, the ADC requires clock and counter inputs as indicated by signals 223 and 225 respectively. Consequently, ADC clock 223 is generated by ANDing the inverted signal 221 with clock 205 through AND gate 211. For error cancellation purposes, the counter requires a delay equivalent to the value determined during characterization. The enable_counter output 217 from FSM 201 effectively delays counter output 225 by the appropriate number of clock cycles.

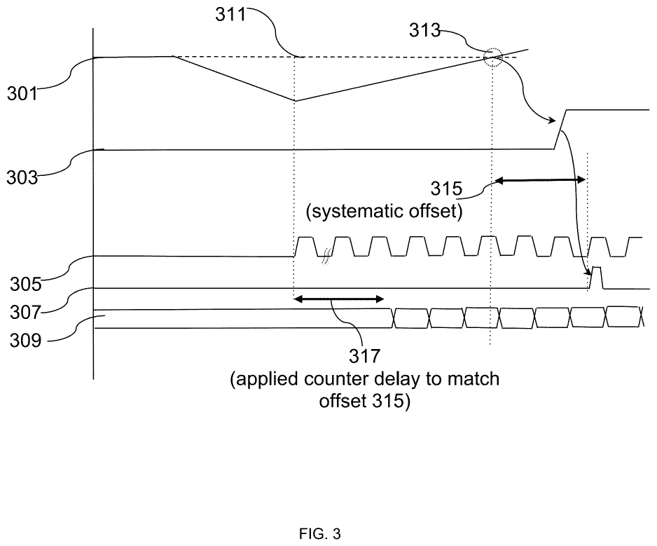

FIG. 3 shows the timing diagram of the ADC operation, according to some embodiments. In this diagram, capacitor node voltage 105 from FIG. 1 is represented by signal 301, signal 303 shows the comparator output, and signal 305 displays the ADC clock provided by the control system 200 depicted in FIG. 2. Signal 307 represents the synchronized pulse derived from the comparator output, while signal 309 shows the delayed counter input. The counter delay magnitude is indicated by marker 317. Ideally, when signal 301 intersects with reference voltage Vref 311 during the evaluation phase (shown by dotted circle 313), comparator output 303 should trigger simultaneously. However, due to systematic errors, the comparator output shifts, as does pulse 307 used for latching the counter value. This time shift is denoted by arrow 315. The delay or shift marked as 317 is applied to the counter output to match offset 315. Consequently, pulse 307 latches the appropriately delayed counter output, effectively canceling the systematic error. By delaying the counter enable relative to the comparator transition, the system effectively aligns the ADC conversion window with a most significant portion of an accumulated analog signal, while discarding less significant portions outside the ADC resolution.

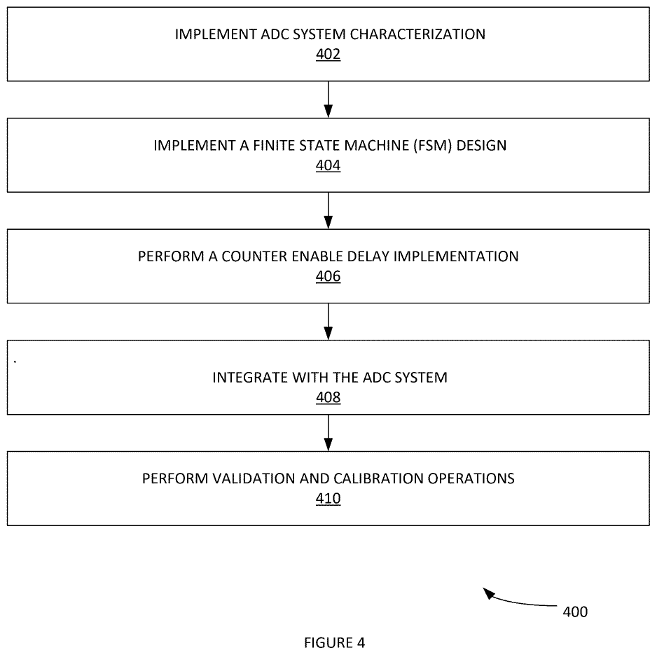

FIG. 4 illustrates a for implementing the error cancellation system in MAC ADC, according to some embodiments. In step 402, process 400 implements ADC system characterization. Process 400 can measure the systematic error timing shift in the ADC system under various process and temperature conditions. Process 400 can quantify the delay between when the capacitor voltage ideally meets Vref and when the comparator actually triggers. Process 400 can document the number of clock cycles that correspond to this systematic error delay. Process 400 can create a mapping between operating conditions and required delay values. The characterization may further determine a capacitance selection or reference ramp configuration that maps an accumulated signal magnitude into an effective conversion range of the ADC.

In step 404, process 400 implements a Finite State Machine (FSM) Design. Process 400 can design the FSM with configurable delay capability for the enable_counter signal. Process 400 can implement trim input functionality to allow programming of specific delay values. Process 400 can ensure the FSM properly generates all required control signals: ref_slope, precharge, and phase_control. Process 400 can verify FSM state transitions meet timing requirements for all operating conditions.

In step 406, process 400 performs a Counter Enable Delay Implementation. Process 400 connects the FSM output to the N-bit up counter's enable input. Process 400 configures the timing mechanism to delay counter enable signal by the appropriate number of clock cycles. Process 400 implements the trim input interface to allow adjustment of delay values based on characterization data. Process 400 ensures proper synchronization between the delayed counter and other ADC components.

In step 408, process 400 integrates with the ADC System. Process 400 connects the FSM control signals to the appropriate ADC components. Process 400 integrates the clock generation logic using the phase_control signal. Process 400 connects the comparator output to the synchronizer flip-flop. Process 400 connects the delayed counter output to the latch input. Process 400 verifies that the full system properly captures the counter value at the appropriate time.

In step 410, process 400 performs validation and calibration operations. Process 400 can test the integrated system under various operating conditions. Process 400 can measure the effectiveness of error cancellation across temperature ranges. Process 400 can fine-tune the trim input values based on testing results. Process 400 can verify that the systematic error has been successfully canceled across all operating conditions. Process 400 can document the optimal trim settings for different implementation scenarios.

It is noted that an error adjustment circuit can be utilized in some embodiments of process 400. The error adjustment circuit can include, inter alia, a finite state machine (FSM) (e.g. as described supra) that delays the enable counter signal. The error adjustment circuit can include a delay trim input that configures the amount of delay. The error adjustment circuit can include a mechanism by which this delay compensates for systematic errors. In this way, the error adjustment functionality that is described functionally supra, can be rendered as a specific named circuit in some examples. The FSM itself is performing the error adjustment by delaying the counter enable signal. In some embodiments, the error adjustment circuit further includes a selectable accumulation capacitance or reference ramp configuration that alters an effective measurement range of the ADC while preserving systematic error cancellation behavior.

In some embodiments, the analog-to-digital converter (ADC) is operated in an environment in which the effective dynamic range of an accumulated analog signal exceeds the native resolution of the ADC. For example, in analog multiply-accumulate (MAC) systems, individual multiplication operations may produce intermediate results of a first bit width, while accumulation across a plurality of rows or elements produces a composite analog signal whose effective range corresponds to a substantially larger bit width. In such cases, the ADC need not resolve the entire accumulated dynamic range, but instead may be configured to capture a most significant portion of the accumulated signal. The system therefore implements mechanisms by which an effective conversion window of the ADC is aligned with a region of interest of the accumulated analog signal, while less significant portions of the signal outside the ADC resolution are disregarded.

In further embodiments, alignment of the ADC conversion window is achieved by selectively modifying at least one characteristic of the ADC or its input signal without increasing the ADC resolution. In some examples, a reference ramp applied during an evaluation phase is adjusted by controlling a ramp current supplied to a reference capacitor, thereby changing a ramp rate and modifying a time required for an accumulated charge to reach a reference threshold. In other examples, an effective accumulation capacitance associated with the ADC is modified by selectively coupling or decoupling one or more capacitance elements, thereby changing a relationship between accumulated charge and voltage at a comparator input. These techniques may be used independently or in combination with systematic error cancellation mechanisms, including counter-enable delay adjustment, to both compensate for systematic timing errors and map an accumulated analog signal into an effective measurement range of the ADC.

### Conclusion

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine-accessible medium compatible with a data processing system (e.g., a computer system), and can be performed in any order (e.g., including using means for achieving the various operations). Accordingly, the specification and drawings are to be regarded in an illustrative rather than a restrictive sense.

1. A system for analog-to-digital conversion with error cancellation, comprising:
an analog-to-digital converter (ADC) comprising:
a capacitor configured to accumulate a charge at a first node;
a reference voltage input coupled to the capacitor;
a comparator having a first input coupled to the first node and a second input coupled to the reference voltage input;
a synchronizer flip-flop coupled to the comparator output;
a latch coupled to the synchronizer flip-flop output and configured to capture a counter value; and
an ADC control system coupled to the analog-to-digital converter, the ADC control system comprising:
a finite state machine (FSM) configured to generate one or more control signals for the ADC operation,
a clock input coupled to the FSM, and
a delay trim input coupled to the FSM and configured to specify a delay value, wherein the FSM is configured to delay an enable counter signal by an integer number of clock cycles defined by the delay trim input,
a counter coupled to receive the enable counter signal from the FSM and configured to generate the counter value that is captured by the ADC latch,
wherein the delayed enable counter signal implements a systematic error cancellation by causing the counter to start counting after a delay that corresponds to the systematic error timing shift in the ADC, and
wherein the ADC control system is further configured to align a conversion window of the ADC with a most significant portion of an accumulated analog signal whose dynamic range exceeds a native resolution of the ADC.

2. The system of claim 1, wherein the FSM comprises a delay mechanism that delays the enable counter signal by a predetermined number of clock cycles, wherein the predetermined number of clock cycles is determined based on characterization of systematic timing errors in the ADC.

3. The system of claim 2, wherein the delay trim input is configured to provide a programmable value to the FSM, and wherein the FSM uses the programmable value to determine the number of clock cycles by which to delay the enable counter signal.

4. The system of claim 1, wherein: the delay trim input comprises a trim pin configured to receive an external signal; the trim pin is configured to provide a programmable value to the FSM; the programmable value is determined based on characterization data of the ADC; and the characterization data identifies the systematic error timing shift in the ADC under specific operating conditions.

5. The system of claim 4, wherein the FSM further generates a phase control signal, and wherein a high-to-low transition on the phase control signal initiates an evaluation phase of the ADC, and wherein the FSM further controls a reference ramp rate applied to the capacitor so as to modify a time required for the capacitor voltage to reach the reference voltage, thereby changing an effective measurement range of the ADC.

6. The system of claim 5, wherein the capacitor configured to accumulate the charge comprises a plurality of selectively switchable capacitance elements, and wherein the ADC control system is configured to electrically couple or decouple one or more of the capacitance elements so as to change an effective accumulation capacitance and thereby alter a measurement range of the ADC.

7. A method for analog-to-digital conversion with error cancellation, comprising:
accumulating a charge at a first node of a capacitor in an analog-to-digital converter (ADC);
comparing, via a comparator, a voltage at the first node with a reference voltage, wherein the comparator has a first input coupled to the first node and a second input coupled to a reference voltage input;
generating, via a finite state machine (FSM), one or more control signals for ADC operation;
receiving a clock input at the FSM;
receiving a delay trim input at the FSM, wherein the delay trim input specifies a delay value;
delaying, via the FSM, an enable counter signal by an integer number of clock cycles defined by the delay trim input;
generating, via a counter coupled to receive the enable counter signal from the FSM, a counter value;
synchronizing, via a synchronizer flip-flop coupled to an output of the comparator, the output of the comparator;
capturing, via a latch coupled to an output of the synchronizer flip-flop, the counter value; and
implementing a systematic error cancellation via the delayed enable counter signal by causing the counter to start counting after a delay that corresponds to a systematic error timing shift in the ADC, and
wherein the method further aligns an ADC conversion window with a most significant portion of an accumulated analog signal.

8. The method of claim 7, further comprising:
delaying, via a delay mechanism in the FSM, the enable counter signal by a predetermined number of clock cycles.

9. The method of claim 8, wherein the predetermined number of clock cycles is determined based on characterization of systematic timing errors in the ADC.

10. The method of claim 9, further comprising:
providing a programmable value to the FSM via the delay trim input.

11. The method of claim 10, further comprising:
determining, via the FSM, the number of clock cycles by which to delay the enable counter signal based on the programmable value.

12. The method of claim 11, further comprising:
receiving an external signal at a trim pin of the delay trim input; providing a programmable value to the FSM via the trim pin.

13. The method of claim 12, further comprising:
determining the programmable value based on characterization data of the ADC.

14. The method of claim 13, further comprising:
identifying, via the characterization data, the systematic error timing shift in the ADC under specific operating conditions.

15. The method of claim 14, further comprising:
generating, via the FSM, a phase control signal.

16. The method of claim 15, further comprising:
initiating an evaluation phase of the ADC upon a high-to-low transition on the phase control signal.

17. The method of claim 16, further comprising:
receiving, at an AND gate, the clock input and an inverted phase control signal.

18. The method of claim 17, further comprising:
generating, via the AND gate, an ADC clock signal.

19. The method of claim 18, further comprising:
providing the ADC clock signal to the ADC.
